(19) United States
(12) Patent Application Publication
(10) Pub. No.: US 2019/0221573 A1
(43) Pub. Date: Jul. 18, 2019

(54) SEMICONDUCTOR DEVICE

(71) Applicant: TOSHIBA MEMORY CORPORATION, Minato-ku (JP)

(72) Inventors: Kenji Koshiishi, Yokohama (JP); Ryota Aburada, Sagamihara (JP); Kazuyuki Yoshimochi, Kuwana (JP)

(73) Assignee: TOSHIBA MEMORY CORPORATION, Minato-ku (JP)

(21) Appl. No.: 16/115,895

(22) Filed: Aug. 29, 2018

(30) Foreign Application Priority Data
Jan. 12, 2018 (JP) 2018-003638

(51) Int. Cl. H01L 27/11573; H01L 27/1157; H01L 27/11582; H01L 23/528; H01L 23/522; H01L 23/00

(52) U.S. Cl. CPC H01L 27/11573; H01L 27/1157; H01L 23/562; H01L 23/5283; H01L 23/5226; H01L 27/11582

(57) ABSTRACT

According to one embodiment, there is provided a semiconductor device including a first laminated body, a first semiconductor columnar member, a first gate insulating film, and a second laminated body. The second laminated body is placed in a periphery of the first laminated body, in which the first insulating layer and a second insulating layer are repeatedly placed one over another in the stacking direction, and has a second stair structure. A width in a first direction of the second laminated body is smaller than a width in the first direction of the first laminated body. The first direction is substantially perpendicular to the stacking direction. A width in a second direction of the second laminated body is smaller than a width in the second direction of the first laminated body. The second direction is substantially perpendicular to the stacking direction and is substantially perpendicular to the first direction.

### CROSS-REFERENCE TO RELATED APPLICATIONS

This application is based upon and claims the benefit of priority from Japanese Patent Application No. 2018-003638, filed on Jan. 12, 2018; the entire contents of which are incorporated herein by reference.

### FIELD

Embodiments described herein relate generally to a semiconductor device.

### BACKGROUND

Semiconductor devices may be formed with a laminated body, in which conductive films and insulating films are alternately stacked one over another, penetrated by semiconductor columnar members. In this case, it is desired that the semiconductor device be highly integrated by increasing the number of stacked layers in the laminated body.

### BRIEF DESCRIPTION OF THE DRAWINGS

FIG. 1 is a perspective view illustrating the configuration of a semiconductor device according to an embodiment;

FIG. 2 is a plan view illustrating the configuration of the semiconductor device according to the embodiment;

FIG. 3 is an enlarged perspective view illustrating the configuration of a laminated body (first laminated body) in the embodiment;

FIG. 4 is an enlarged cross-sectional view illustrating the configuration of laminated bodies (the first laminated body and a second laminated body) in the embodiment;

FIGS. 5A and 5B are enlarged perspective views illustrating the configuration of the laminated body (second laminated body) in the embodiment;

FIGS. 6A and 6B are diagrams illustrating stress relief in the embodiment; and

FIG. 7 is a plan view illustrating the configuration of a semiconductor device according to a modified example of the embodiment.

### DETAILED DESCRIPTION

In general, according to one embodiment, there is provided a semiconductor device including a first laminated body, a first semiconductor columnar member, a first gate insulating film, and a second laminated body. In the first laminated body, a conductive film and a first insulating layer are repeatedly placed one over another in a stacking direction. The first laminated body has a first stair structure. The first semiconductor columnar member extends through the first laminated body in the stacking direction. The first gate insulating film surrounds the first semiconductor columnar member in plan view and extends through the first laminated body in the stacking direction. The second laminated body is placed in a periphery of the first laminated body, in which the first insulating layer and a second insulating layer are repeatedly placed one over another in the stacking direction, and has a second stair structure. A width in a first direction of the second laminated body is smaller than a width in the first direction of the first laminated body. The first direction is substantially perpendicular to the stacking direction. A width in a second direction of the second laminated body is smaller than a width in the second direction of the first laminated body. The second direction is substantially perpendicular to the stacking direction and is substantially perpendicular to the first direction.

Exemplary embodiments of a semiconductor device will be explained below in detail with reference to the accompanying drawings. The present invention is not limited to the following embodiments.

### Embodiment

As to a semiconductor device in which a laminated body having conductive films and insulating layers alternately stacked one over another is penetrated by semiconductor columnar members to form a three-dimensional arrangement of memory cells, the storage capacity can be increased by increasing the number of stacked layers, and hence the necessity of using a more advanced patterning technique can be reduced, so that the cost per bit can be easily reduced.

A memory having a three-dimensional structure is configured such that the intersections of conductive films and semiconductor columnar members function as memory cells, so that the plurality of memory cells are arranged three-dimensionally. With the memory array area in which the plurality of memory cells are arranged three-dimensionally, in order to improve accessibility to the three-dimensional arrangement, a plurality of lines may be made to lead out in a stairs shape from the memory array area into a stairs region on the outside thereof. And a three-dimensional NAND flash memory may be configured such that in the stairs region, a plurality of via plugs extending in a depth direction from predetermined interconnect layers to different depths are connected to the plurality of lines made to lead out in the stairs shape.

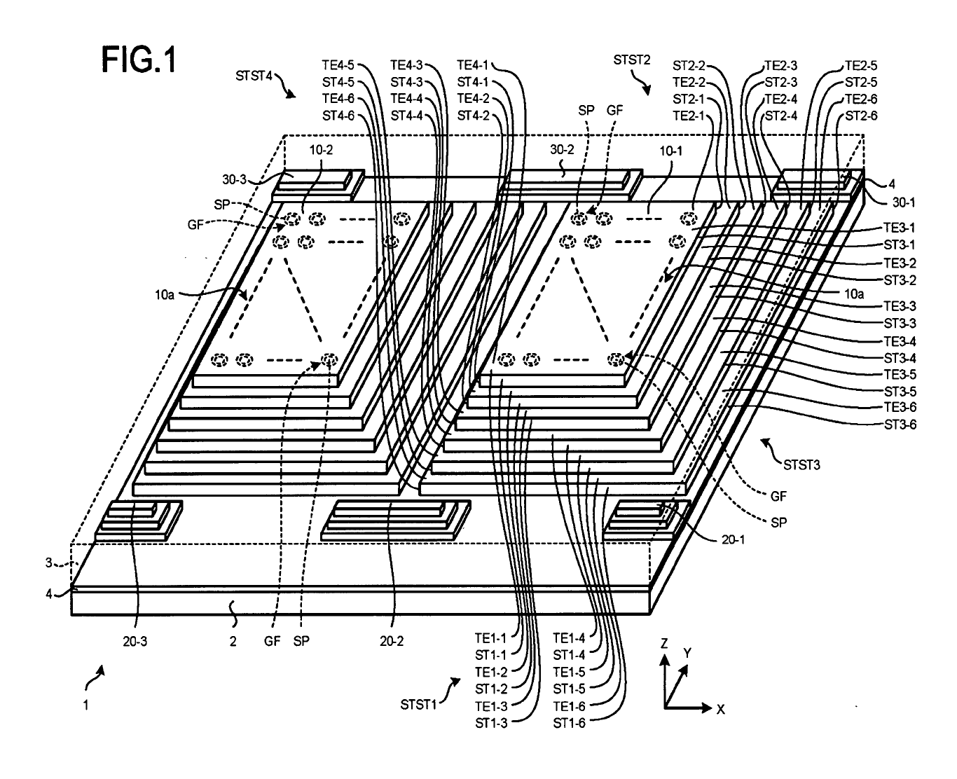

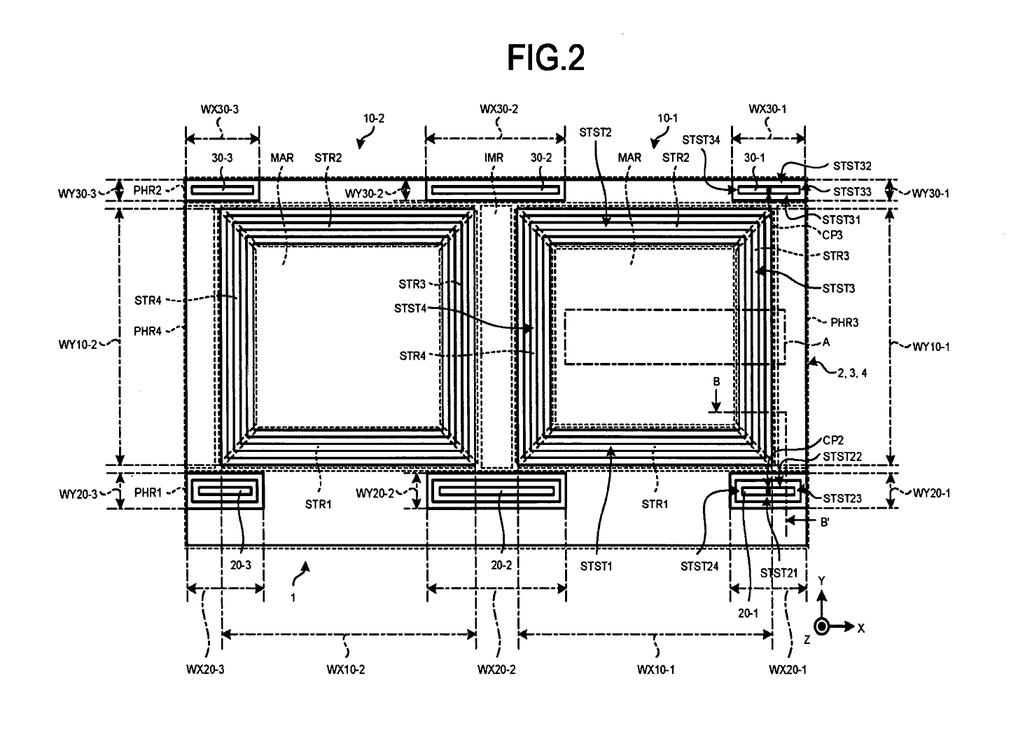

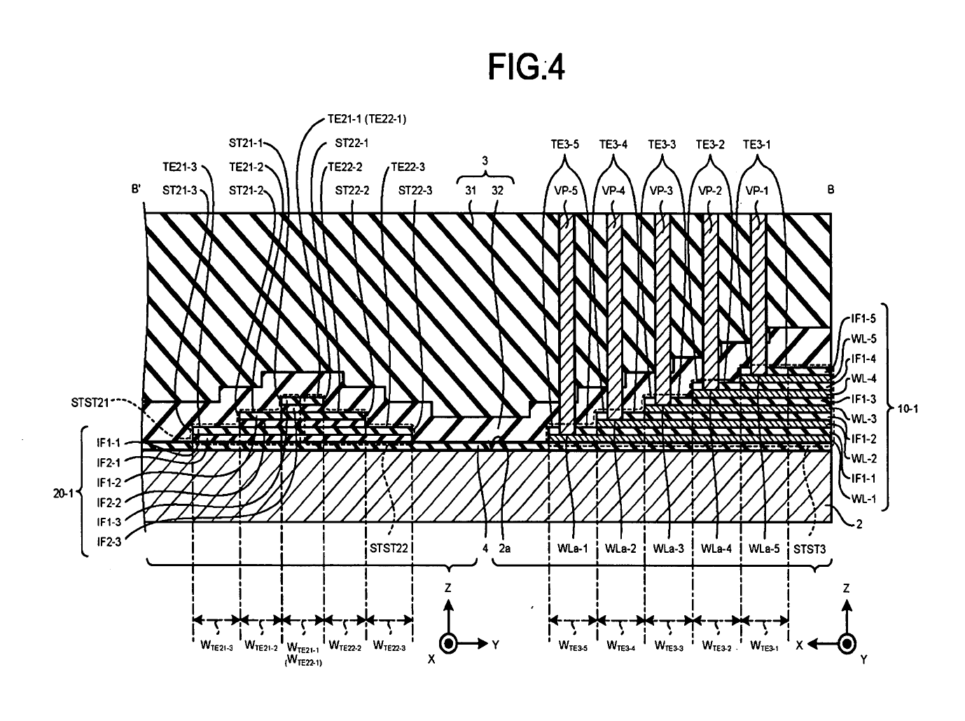

For example, a semiconductor device 1 is configured as shown in FIGS. 1 and 2. FIG. 1 is a perspective view illustrating the configuration of the semiconductor device 1. FIG. 2 is a plan view illustrating the configuration of the semiconductor device 1. Hereinafter, description will be made supposing that a Z direction is a direction substantially perpendicular to a surface 2a of a substrate 2 (see FIG. 4) and that an X direction and Y direction are two directions orthogonal to each other in a plane substantially perpendicular to the Z direction. Further, the direction parallel to the Z direction and going from the substrate 2 toward an interlayer insulating film 3 may be called the +Z direction, and the direction parallel to the Z direction and going from the interlayer insulating film 3 toward the substrate 2 may be called the −Z direction. The direction parallel to the Y direction and going from the front side of FIG. 1 toward the back side may be called the +Y direction, and the direction parallel to the Y direction and going from the back side of FIG. 1 toward the front side may be called the −Y direction. The direction parallel to the X direction and going from the left side of FIG. 1 toward the right side may be called the +X direction, and the direction parallel to the X direction and going from the right side of FIG. 1 toward the left side may be called the −X direction.

The semiconductor device 1 includes the substrate 2, the interlayer insulating film 3, an insulating film 4, a laminated body (first laminated body) 10-1, a laminated body (fourth laminated body) 10-2, a plurality of gate insulating films GF, and a plurality of semiconductor columnar members SP.

The substrate 2 can be formed of a material consisting primarily of a semiconductor (e.g., silicon). The insulating film 4 covers the surface 2a of the substrate 2. The insulating film 4 can be formed of a material consisting primarily of an insulator (e.g., silicon oxide). The substrate 2 is shaped almost like a plate.

The laminated bodies 10-1, 10-2 are placed on the substrate 2 via the insulating film 4. The laminated bodies 10-1 and 10-2 are placed apart (e.g., in the X direction) from each other on the substrate 2. The laminated body 10-1 is shaped almost like a prismoid and, in XY plan view, is surrounded by a peripheral region PHR1 on the −Y side, a peripheral region PHR2 on the +Y side, a peripheral region PHR3 on the +X side, and an intermediate region IMR. The width along the X direction of the laminated body 10-1 can be made smaller than the width along the X direction of the substrate 2 (e.g., about half of the width along the X direction of the substrate 2). The width along the Y direction of the laminated body 10-1 is smaller than the width along the Y direction of the substrate 2. The laminated body 10-2 is shaped almost like a prismoid and, in XY plan view, is surrounded by the peripheral region PHR1 on the −Y side, the peripheral region PHR2 on the +Y side, a peripheral region PHR4 on the −X side, and the intermediate region IMR. The width along the X direction of the laminated body 10-2 can be made smaller than the width along the X direction of the substrate 2 (e.g., about half of the width along the X direction of the substrate 2). The width along the Y direction of the laminated body 10-2 is smaller than the width along the Y direction of the substrate 2.

The interlayer insulating film 3 covers each laminated body 10 (when the laminated bodies 10-1, 10-2 are not distinguished, they are referred to simply as a laminated body 10) and covers the surface 2a of the substrate 2 via the insulating film 4 (see FIG. 4). The interlayer insulating film 3 can be formed of a material consisting primarily of an insulator (e.g., silicon oxide).

Each of the semiconductor columnar member SP can be in the form of a semiconductor shaped like a circular column or a cylinder. Furthermore, each of the semiconductor columnar member SP may be in the form of a semiconductor shaped like a tube with its inside filled with an insulating core film.

The laminated body 10-1 has a memory array area MAR and a plurality of stairs regions STR1 to STR4. In XY plan view, the stairs regions STR1 to STR4 are placed on the outside of the memory array area MAR and surround the memory array area MAR. The stairs region STR1 is adjacent to the memory array area MAR on the −Y side thereof. The stairs region STR2 is adjacent to the memory array area MAR on the +Y side thereof. The stairs region STR3 is adjacent to the memory array area MAR on the +X side thereof. The stairs region STR4 is adjacent to the memory array area MAR on the −X side thereof. In XY plan view, the memory array area MAR is in a substantially rectangular shape; the stairs region STR1 is shaped almost like an isosceles trapezoid having its top on the +Y side; the stairs region STR2 is shaped almost like an isosceles trapezoid having its top on the −Y side; the stairs region STR3 is shaped almost like an isosceles trapezoid having its top on the −X side; and the stairs region STR4 is shaped almost like an isosceles trapezoid having its top on the +X side.

The laminated body 10-1 has a plurality of stair structures STST1 to STST4 in the plurality of stairs regions STR1 to STR4.

The stair structure STST1 is placed in the stairs region STR1 of the laminated body 10-1 and is adjacent to the memory array area MAR on the −Y side thereof. The stair structure STST1 becomes lower stepwise in height above the surface 2a of the substrate 2 when going away in the −Y direction from the memory array area MAR. The stair structure STST1 has a plurality of terraces TE1-1 to TE1-6 and a plurality of steps ST1-1 to ST1-6. In XY plan view, when going away in the −Y direction from the memory array area MAR, the terrace TE1-1, step ST1-1, terrace TE1-2, step ST1-2, terrace TE1-3, step ST1-3, terrace TE1-4, step ST1-4, terrace TE1-5, step ST1-5, terrace TE1-6, and step ST1-6 are arranged in that order. Each terrace TE1-1 to TE1-6 extends along XY directions. Each step ST1-1 to ST1-6 extends along XZ directions.

Letting H_{TE1-1}, H_{TE1-2}, H_{TE1-3}, H_{TE1-4}, H_{TE1-5}, and H_{TE1-6} be the heights along the Z direction of the terraces TE1-1, TE1-2, TE1-3, TE1-4, TE1-5, and TE1-6 respectively above the surface 2a of the substrate 2 (see FIG. 4), the relation given by the following formula 1 holds.

H_{TE1-1}>H_{TE1-2}>H_{TE1-3}>H_{TE1-4}>H_{TE1-5}>H_{TE1-6} Formula 1

The differences between adjacent heights from among the heights along the Z direction of the terraces TE1-1, TE1-2, TE1-3, TE1-4, TE1-5, and TE1-6 are substantially even, and the following formula 2 holds.

H_{TE1-1}−H_{TE1-2}≈H_{TE1-2}−H_{TE1-3}≈H_{TE1-3}−H_{TE1-4}≈H_{TE1-4}−H_{TE1-5}≈H_{TE1-5}−H_{TE1-6}≈H_{TE1-6} Formula 2

Accordingly, letting G_{ST1-1}, G_{ST1-2}, G_{ST1-3}, G_{ST1-4}, G_{ST1-5}, and G_{ST1-6} be the widths along the Z direction of the steps ST1-1, ST1-2, ST1-3, ST1-4, ST1-5, and ST1-6 respectively, they are substantially even, and the relation given by the following formula 3 holds.

G_{ST1-1}≈G_{ST1-2}≈G_{ST1-3}≈G_{ST1-4}≈G_{ST1-5}≈G_{ST1-6} Formula 3

Letting W_{TE1-1}, W_{TE1-2}, W_{TE1-3}, W_{TE1-4}, W_{TE1-5}, and W_{TE1-6} be the widths along the Y direction of the terraces TE1-1, TE1-2, TE1-3, TE1-4, TE1-5, and TE1-6 respectively, the relation given by the following formula 4 holds.

W_{TE1-1}≈W_{TE1-2}≈W_{TE1-3}≈W_{TE1-4}≈W_{TE1-5}≈W_{TE1-6} Formula 4

The stair structure STST2 is placed in the stairs region STR2 of the laminated body 10-1 and is adjacent to the memory array area MAR on the +Y side thereof. The stair structure STST2 becomes lower stepwise in height above the surface 2a of the substrate 2 when going away in the +Y direction from the memory array area MAR. The stair structure STST2 has a plurality of terraces TE2-1 to TE2-6 and a plurality of steps ST2-1 to ST2-6. In XY plan view, when going away in the +Y direction from the memory array area MAR, the terrace TE2-1, step ST2-1, terrace TE2-2, step ST2-2, terrace TE2-3, step ST2-3, terrace TE2-4, step ST2-4, terrace TE2-5, step ST2-5, terrace TE2-6, and step ST2-6 are arranged in that order. Each terrace TE2-1 to TE2-6 extends along XY directions. Each step ST2-1 to ST2-6 extends along XZ directions.

Letting H_{TE2-1}, H_{TE2-2}, H_{TE2-3}, H_{TE2-4}, H_{TE2-5}, and H_{TE2-6} be the heights along the Z direction of the terraces TE2-1, TE2-2, TE2-3, TE2-4, TE2-5, and TE2-6 respectively above the surface 2a of the substrate 2 (see FIG. 4), the relation given by the following formula 5 holds.

H_{TE2-1}>H_{TE2-2}>H_{TE2-3}>H_{TE2-4}>H_{TE2-5}>H_{TE2-6} Formula 5

The differences between adjacent heights from among the heights along the Z direction of the terraces TE2-1, TE2-2, TE2-3, TE2-4, TE2-5, and TE2-6 are substantially even, and the following formula 6 holds.

H_{TE2-1}−H_{TE2-2}≈H_{TE2-2}−H_{TE2-3}≈H_{TE2-3}−H_{TE2-4}≈H_{TE2-4}−H_{TE2-5}≈H_{TE2-5}−H_{TE2-6}≈H_{TE2-6} Formula 6

Accordingly, letting G_{ST2-1}, G_{ST2-2}, G_{ST2-3}, G_{ST2-4}, G_{ST2-5}, and G_{ST2-6} be the widths along the Z direction of the steps ST2-1, ST2-2, ST2-3, ST2-4, ST2-5, and ST2-6 respectively, they are substantially even, and the relation given by the following formula 7 holds.

G_{ST2-1}≈G_{ST2-2}≈G_{ST2-3}≈G_{ST2-4}≈G_{ST2-5}≈G_{ST2-6} Formula 7

Letting W_{TE2-1}, W_{TE2-2}, W_{TE2-3}, W_{TE2-4}, W_{TE2-5}, and W_{TE2-6} be the widths along the Y direction of the terraces TE2-1, TE2-2, TE2-3, TE2-4, TE2-5, and TE2-6 respectively, the relation given by the following formula 8 holds.

W_{TE2-1}≈W_{TE2-2}≈W_{TE2-3}≈W_{TE2-4}≈W_{TE2-5}≈W_{TE2-6} Formula 8

The stair structure STST3 is placed in the stairs region STR3 of the laminated body 10-1 and is adjacent to the memory array area MAR on the +X side thereof. The stair structure STST3 becomes lower stepwise in height above the surface 2a of the substrate 2 when going away in the +X direction from the memory array area MAR. The stair structure STST3 has a plurality of terraces TE3-1 to TE3-6 and a plurality of steps ST3-1 to ST3-6. In XY plan view, when going away in the +X direction from the memory array area MAR, the terrace TE3-1, step ST3-1, terrace TE3-2, step ST3-2, terrace TE3-3, step ST3-3, terrace TE3-4, step ST3-4, terrace TE3-5, step ST3-5, terrace TE3-6, and step ST3-6 are arranged in that order. Each terrace TE3-1 to TE3-6 extends along XY directions. Each step ST3-1 to ST3-6 extends along YZ directions.

Letting H_{TE3-1}, H_{TE3-2}, H_{TE3-3}, H_{TE3-4}, H_{TE3-5}, and H_{TE3-6} be the heights along the Z direction of the terraces TE3-1, TE3-2, TE3-3, TE3-4, TE3-5, and TE3-6 respectively above the surface 2a of the substrate 2 (see FIG. 4), the relation given by the following formula 9 holds.

H_{TE3-1}>H_{TE3-2}>H_{TE3-3}>H_{TE3-4}>H_{TE3-5}>H_{TE3-6} Formula 9

The differences between adjacent heights from among the heights along the Z direction of the terraces TE3-1, TE3-2, TE3-3, TE3-4, TE3-5, and TE3-6 are substantially even, and the following formula 10 holds.

H_{TE3-1}−H_{TE3-2}≈H_{TE3-2}−H_{TE3-3}≈H_{TE3-3}−H_{TE3-4}≈H_{TE3-4}−H_{TE3-5}≈H_{TE3-5}−H_{TE3-6}≈H_{TE3-6} Formula 10

Accordingly, letting G_{ST3-1}, G_{ST3-2}, G_{ST3-3}, G_{ST3-4}, G_{ST3-5}, and G_{ST3-6} be the widths along the Z direction of the steps ST3-1, ST3-2, ST3-3, ST3-4, ST3-5, and ST3-6 respectively, they are substantially even, and the relation given by the following formula 11 holds.

G_{ST3-1}≈G_{ST3-2}≈G_{ST3-3}≈G_{ST3-4}≈G_{ST3-5}≈G_{ST3-6} Formula 11

Letting W_{TE3-1}, W_{TE3-2}, W_{TE3-3}, W_{TE3-4}, W_{TE3-5}, and W_{TE3-6} be the widths along the X direction of the terraces TE3-1, TE3-2, TE3-3, TE3-4, TE3-5, and TE3-6 respectively (see FIG. 4), the relation given by the following formula 12 holds.

W_{TE3-1}≈W_{TE3-2}≈W_{TE3-3}≈W_{TE3-4}≈W_{TE3-5}≈W_{TE3-6} Formula 12

The stair structure STST4 is placed in the stairs region STR4 of the laminated body 10-1 and is adjacent to the memory array area MAR on the −X side thereof. The stair structure STST4 becomes lower stepwise in height above the surface 2a of the substrate 2 when going away in the −X direction from the memory array area MAR. The stair structure STST4 has a plurality of terraces TE4-1 to TE4-6 and a plurality of steps ST4-1 to ST4-6. In XY plan view, when going away in the −X direction from the memory array area MAR, the terrace TE4-1, step ST4-1, terrace TE4-2, step ST4-2, terrace TE4-3, step ST4-3, terrace TE4-4, step ST4-4, terrace TE4-5, step ST4-5, terrace TE4-6, and step ST4-6 are arranged in that order. Each terrace TE4-1 to TE4-6 extends along XY directions. Each step ST4-1 to ST4-6 extends along YZ directions.

Letting H_{TE4-1}, H_{TE4-2}, H_{TE4-3}, H_{TE4-4}, H_{TE4-5}, and H_{TE4-6} be the heights along the Z direction of the terraces TE4-1, TE4-2, TE4-3, TE4-4, TE4-5, and TE4-6 respectively above the surface 2a of the substrate 2 (see FIG. 4), the relation given by the following formula 13 holds.

H_{TE4-1}>H_{TE4-2}>H_{TE4-3}>H_{TE4-4}>H_{TE4-5}>H_{TE4-6} Formula 13

The differences between adjacent heights from among the heights along the Z direction of the terraces TE4-1, TE4-2, TE4-3, TE4-4, TE4-5, and TE4-6 are substantially even, and the following formula 14 holds.

H_{TE4-1}−H_{TE4-2}≈H_{TE4-2}−H_{TE4-3}≈H_{TE4-3}−H_{TE4-4}≈H_{TE4-4}−H_{TE4-5}≈H_{TE4-5}−H_{TE4-6}≈H_{TE4-6} Formula 14

Accordingly, letting G_{ST4-1}, G_{ST4-2}, G_{ST4-3}, G_{ST4-4}, G_{ST4-5}, and G_{ST4-6} be the widths along the Z direction of the steps ST4-1, ST4-2, ST4-3, ST4-4, ST4-5, and ST4-6 respectively, they are substantially even, and the relation given by the following formula 15 holds.

G_{ST4-1}≈G_{ST4-2}≈G_{ST4-3}≈G_{ST4-4}≈G_{ST4-5}≈G_{ST4-6} Formula 15

Letting W_{TE4-1}, W_{TE4-2}, W_{TE4-3}, W_{TE4-4}, W_{TE4-5}, and W_{TE4-6} be the widths along the X direction of the terraces TE4-1, TE4-2, TE4-3, TE4-4, TE4-5, and TE4-6 respectively, the relation given by the following formula 16 holds.

W_{TE4-1}≈W_{TE4-2}≈W_{TE4-3}≈W_{TE4-4}≈W_{TE4-5}≈W_{TE4-6} Formula 16

Note that the configuration of the laminated body 10-2 is the same as that of the laminated body 10-1.

The plurality of semiconductor columnar members SP are placed in the memory array area MAR of each laminated body 10 as shown in FIG. 1 and arranged in the X and Y directions. Each semiconductor columnar member SP is formed, for example, in an almost cylindrical shape with the Z direction as its axis and extends through the laminated body 10 in a direction substantially perpendicular to the principal surface 10a of the laminated body 10 (substantially in the Z direction). Each semiconductor columnar member SP may be formed of a semiconductor material in an almost tubular shape with a bottom and have a structure in which a core insulating material is provided inside the semiconductor material. In the laminated body 10, a conductive film WL and an insulating layer (first insulating film) IF1 are repeatedly stacked one over another. In the laminated body 10, the principal surface 10a is the highest surface in height above the surface 2a of the substrate 2 (the top of the uppermost layer of the laminated body 10, e.g., the uppermost insulating film IF1) and, at the −Y side thereof, includes the top of the terrace TE1-1, at the +Y side thereof, includes the top of the terrace TE2-1, at the +X side thereof, includes the top of the terrace TE3-1, and, at the −X side thereof, includes the top of the terrace TE4-l. The semiconductor columnar member SP can function as the channel regions (active regions) in memory cells.

The plurality of gate insulating films GF are placed corresponding to the plurality of semiconductor columnar members SP in the memory array area MAR of each laminated body 10 and arranged in the X and Y directions. Each gate insulating film GF is placed between a semiconductor columnar member SP and the laminated body 10. Each gate insulating film GF is formed in an almost tubular shape with, e.g., the Z direction as its axis and extends through the laminated body 10 in a direction substantially perpendicular to the principal surface 10a of the laminated body 10 (substantially in the Z direction). That is, each gate insulating film GF surrounds a semiconductor columnar member SP in XY plan view. Each gate insulating film GF is, in XZ cross-sectional view, in contact with the side surface of the semiconductor columnar member SP and extends in the Z direction. The gate insulating film GF is configured to have a charge storage capability and has, e.g., an ONO three-layered structure. In the memory array area MAR, charge can be stored in the gate insulating film GF at the intersections of the semiconductor columnar member SP and conductive films WL. In this case, the conductive film WL functions as a control gate in a memory cell.

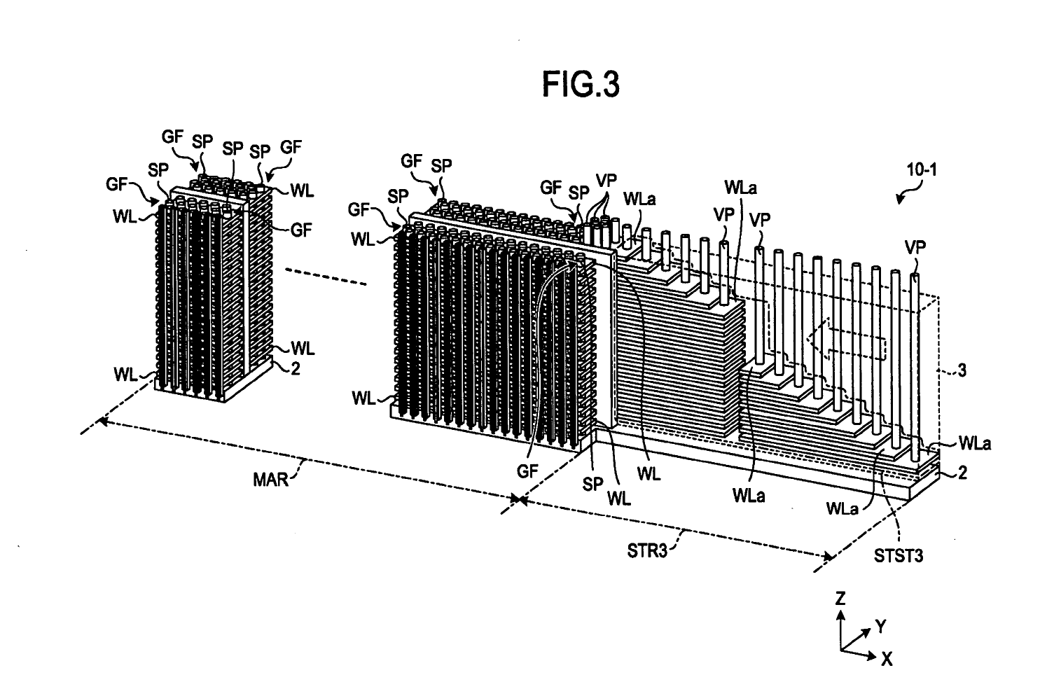

More specifically, each laminated body 10 is configured as shown in FIGS. 3 and 4. FIG. 3 is an enlarged perspective view illustrating the configuration of the laminated body 10-1, showing the configuration of part A of FIG. 2. In FIG. 3, insulating films (such as insulating films IF1 and an insulating film 32 shown in FIG. 4) except the interlayer insulating film 3 are omitted from illustration for simplicity of illustration. FIG. 4 is an enlarged cross-sectional view illustrating the configuration of the laminated body 10-1, taken along line B-B′ of FIG. 2. Although FIGS. 3 and 4 illustrate the configuration of the laminated body 10-1, the configuration of the laminated body 10-2 is the same as that of the laminated body 10-1.

In the laminated body 10, a conductive film WL and an insulating film (first insulating layer) IF1 are repeatedly stacked one over another. FIG. 3 illustrates a configuration where a conductive film WL and an insulating film IF1 are alternately stacked one over another multiple times, as that of the laminated body 10 (where insulating films IF1 are omitted from illustration for simplicity of illustration). FIGS. 1, 2, 4 illustrate a configuration where a conductive film WL and an insulating film IF1 are alternately stacked one over another five or six times, as that of the laminated body 10-1. In the laminated body 10-1 shown in FIG. 4, on the substrate 2 and the insulating film 4, a conductive film WL-1, an insulating film IF1-1, a conductive film WL-2, an insulating film IF1-2, a conductive film WL-3, an insulating film IF1-3, a conductive film WL-4, an insulating film IF1-4, a conductive film WL-5, and an insulating film IF1-5 are stacked one over another in that order. The configuration of the laminated body 10-2 is the same as that of the laminated body 10-1. In the laminated bodies 10-1, 10-2, air gaps may be formed between layers of conductive films WL.

In the memory array area MAR, the plurality of conductive films WL (or WL-1 to WL-5) stacked (arranged in the Z direction) are penetrated by gate insulating films GF and semiconductor columnar members SP. Each conductive film WL (or WL-1 to WL-5) functions as a word line connected to the control gate of a memory cell (transistor). Each gate insulating film GF extends through the plurality of conductive films WL (or WL-1 to WL-5) and is placed touching the inner circumferential surfaces of the plurality of conductive films WL (or WL-1 to WL-5) facing the hole extending through the plurality of conductive films WL (or WL-1 to WL-5). Each gate insulating film GF includes a charge storage film having a charge storage capability. Each gate insulating film GF is formed of, e.g., an ONO film. The ONO film has a three-layered structure where a silicon nitride film is sandwiched between two silicon oxide films. Each gate insulating film GF includes the silicon nitride film in the ONO film as the charge storage film and can store charge in the silicon nitride film. Each semiconductor columnar member SP is connected on the +Z side to a bit line (not shown) extending in the Y direction.

In the stairs region STR, in order to apply a voltage individually to the control gates of memory cells (transistors) arranged in the Z direction, word lines of the respective stairs (conductive films WL-1 to WL-5 of the respective stairs) connected to the control gates are made to lead out in the X direction in a stairs shape and joined to a plurality of via plugs VP-1 to VP-5 different in depth along the Z direction.

For example, FIG. 4 illustrates the five-stair structure STST3. The top of the end of the insulating film IF1-5 in the stair structure STST3 made to lead out in the X direction forms the terrace TE3-1, and the lead portion WLa-5 of the conductive film WL-5 made to lead out in the X direction is covered by the end of the insulating film IF1-5 forming the terrace TE3-1. The via plug VP-1 extends in the Z direction through the end of the insulating film IF1-5 forming the terrace TE3-1 to be electrically connected to the lead portion WLa-5.

The top of the end of the insulating film IF1-4 in the stair structure STST3 made to lead out in the X direction forms the terrace TE3-2, and the lead portion WLa-4 of the conductive film WL-4 made to lead out in the X direction is covered by the end of the insulating film IF1-4 forming the terrace TE3-2. The via plug VP-2 extends in the Z direction through the end of the insulating film IF1-4 forming the terrace TE3-2 to be electrically connected to the lead portion WLa-4.

The top of the end of the insulating film IF1-3 in the stair structure STST3 made to lead out in the X direction forms the terrace TE3-3, and the lead portion WLa-3 of the conductive film WL-3 made to lead out in the X direction is covered by the end of the insulating film IF1-3 forming the terrace TE3-3. The via plug VP-3 extends in the Z direction through the end of the insulating film IF1-3 forming the terrace TE3-3 to be electrically connected to the lead portion WLa-3.

The top of the end of the insulating film IF1-2 in the stair structure STST3 made to lead out in the X direction forms the terrace TE3-4, and the lead portion WLa-2 of the conductive film WL-2 made to lead out in the X direction is covered by the end of the insulating film IF1-2 forming the terrace TE3-4. The via plug VP-4 extends in the Z direction through the end of the insulating film IF1-2 forming the terrace TE3-4 to be electrically connected to the lead portion WLa-2.

The top of the end of the insulating film IF1-1 in the stair structure STST3 made to lead out in the X direction forms the terrace TE3-5, and the lead portion WLa-1 of the conductive film WL-1 made to lead out in the X direction is covered by the end of the insulating film IF1-1 forming the terrace TE3-5. The via plug VP-5 extends in the Z direction through the end of the insulating film IF1-1 forming the terrace. TE3-5 to be electrically connected to the lead portion WLa-1.

The interlayer insulating film 3 has an insulating film 31 and an insulating film 32. The insulating film 31 can be formed of a material consisting primarily of silicon oxide. The insulating film 32 can function as an etching stopper in making holes in the insulating film 31 by etching to be filled with conductive material to form the via plugs VP and can be formed of a material consisting primarily of silicon nitride.

In the semiconductor device 1, each laminated body 10 is covered by the interlayer insulating film 3, and because the ratio of deformation due to variation in ambient environment such as temperature variation (the ratio of contracting or expanding volume) is different between the laminated body 10 and the interlayer insulating film 3, compressive stress by which the interlayer insulating film 3 pushes the laminated body 10 can occur as indicated by a broken-line arrow in FIG. 3. This tendency is likely to become more noticeable as the number of stacked conductive films WL and insulating films IF1 in the laminated body 10 increases. If the compressive stress of the interlayer insulating film 3 increases, a failure due to the compressive stress may occur in the semiconductor device 1.

For example, when the compressive stress of the interlayer insulating film 3 increases, because the interlayer insulating film 3 is in contact with not only the terraces (XY-direction surfaces) but also steps (YZ-direction surfaces) of the stair structure STST3 as shown in FIG. 3, the stair structure STST3 may suffer compressive stress of, e.g., the −X direction. Under compressive stress of the −X direction, the conductive films WL warp, so that a short circuit between conductive films WL adjacent in the Z direction may occur or that a crack may occur in a conductive film WL, resulting in a disconnection.

Or, for example, as shown in FIG. 3, because the via plugs VP extend in the Z direction to be connected to the terraces (XY-direction surfaces) in the stair structure STST3, the via plugs VP may suffer compressive stress of the −X direction when the compressive stress of the interlayer insulating film 3 increases. Under compressive stress of the −X direction, the connection positions of via plugs VP deviate from the desired terraces, so that a short circuit with an adjacent via plug VP and/or conductive film WL on the −X side thereof may occur or that a crack may occur in a via plugs VP, resulting in a disconnection.

Accordingly, in the present embodiment, by placing laminated bodies 20 having a stair structure in a periphery the laminated body 10, the compressive stress of the interlayer insulating film 3 on the laminated body 10 is relieved, so that the semiconductor device 1 can be easily highly integrated.

Specifically, the semiconductor device 1 shown in FIG. 1 further includes laminated bodies (second laminated bodies) 20-1 to 20-3 and laminated bodies (third laminated bodies) 30-1 to 30-3. The laminated bodies 20-1 to 20-3 are placed in a periphery region PHR1 on the −Y side shown in FIG. 2. The laminated bodies 30-1 to 30-3 are places in a periphery region PHR2 on the +Y side. As shown in FIG. 2, in XY plan view, each laminated body 20 (when the laminated bodies 20-1 to 20-3 are not distinguished, they are referred to simply as a laminated body 20) is smaller in area than the laminated body 10. For example, a width in the X direction of each laminated body 20 is smaller than a width in the X direction of each laminated body 10. A width in the Y direction of each laminated body 20 is smaller than a width in the Y direction of each laminated body 10. In XY plan view, each laminated body 30 (when the laminated bodies 30-1 to 30-3 are not distinguished, they are referred to simply as a laminated body 30) is smaller in area than the laminated body 10. For example, a width in the X direction of each laminated body 30 is smaller than a width in the X direction of each laminated body 10. A width in the Y direction of each laminated body 30 is smaller than a width in the Y direction of each laminated body 10.

The stress of the interlayer insulating film 3 tends to focus on corners and their neighborhoods of the planar shape of the laminated body 10. Thus, each laminated body 20 can be placed near a corner of the laminated body 10.

For example, the laminated body 20-1 is placed near the corner on the +X side and the −Y side of the laminated body 10-1 in the periphery region PHR1. The laminated body 20-2 is placed near the corner on the −X side and the −Y side of the laminated body 10-1 and near the corner on the +X side and the −Y side of the laminated body 10-2 in the periphery region PHR1. The laminated body 20-3 is placed near the corner on the −X side and the −Y side of the laminated body 10-2 in the periphery region PHR1. The laminated body 30-1 is placed near the corner on the +X side and the +Y side of the laminated body 10-1 in the periphery region PHR2. The laminated body 30-2 is placed near the corner on the −X side and the +Y side of the laminated body 10-1 and near the corner on the +X side and the +Y side of the laminated body 10-2 in the periphery region PHR2. The laminated body 30-3 is placed near the corner on the −X side and the +Y side of the laminated body 10-2 in the periphery region PHR2.

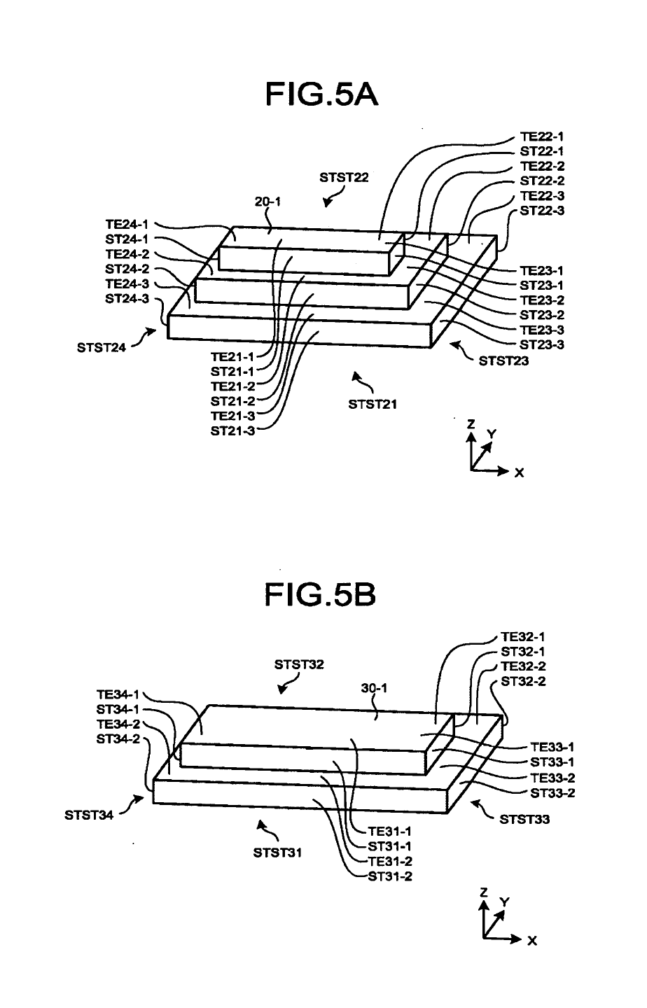

Each laminated body 20 has a stair structure. For example, as shown in FIG. 5A, the laminated body 20-1 has a plurality of stair structures STST21 to STST24. FIG. 5A is an enlarged perspective view illustrating the configuration of the laminated body 20.

The stair structure STST21 is placed on the −Y side of the center CP2 (see FIG. 2) of the laminated body 20-1. The stair structure STST21 becomes lower stepwise in height above the surface 2a of the substrate 2 when going away in the −Y direction from the center CP2. The stair structure STST21 has a plurality of terraces TE21-1 to TE21-3 and a plurality of steps ST21-1 to ST21-3. In XY plan view, when going away in the −Y direction from the center CP2, the terrace TE21-1, step ST21-1, terrace TE21-2, step ST21-2, terrace TE21-3, and step ST21-3 are arranged in that order. Each terrace TE21-1 to TE21-3 extends along XY directions. Each step ST21-1 to ST21-3 extends along XZ directions.

Letting H_{TE21-1}, H_{TE21-2}, and H_{TE21-3} be the heights along the Z direction of the terraces TE21-1, TE21-2, and TE21-3 respectively above the surface 2a of the substrate 2 (see FIG. 4), the relation given by the following formula 17 holds.

H_{TE21-1}>H_{TE21-2}>H_{TE21-3} Formula 17

The differences between adjacent heights from among the heights along the Z direction of the terraces TE21-1, TE21-2, and TE21-3 are substantially even, and the following formula 18 holds.

H_{TE21-1}−H_{TE21-2}≈H_{TE21-2}−H_{TE21-3}≈H_{TE21-3} Formula 18

Accordingly, letting G_{ST21-1}, G_{ST21-2}, and G_{ST21-3} be the widths along the Z direction of the steps ST21-1, ST21-2, and ST21-3 respectively, they are substantially even, and the relation given by the following formula 19 holds. In this case, the widths along the Z direction of the steps ST21-1, ST21-2, and ST21-3 can be made substantially the same as the widths along the Z direction of the steps ST1-1, ST1-2, ST1-3, ST1-4, ST1-5, and ST1-6 of the stair structure STST1.

G_{ST21-1}≈G_{ST21-2}≈G_{ST21-3}(≈G_{ST1-1}≈G_{ST1-2}≈G_{ST1-3}≈G_{ST1-4}≈G_{ST1-5}≈G_{ST1-6}) Formula 19

Letting W_{TE21-1}, W_{TE21-2}, and W_{TE21-3} be the widths along the Y direction of the terraces TE21-1, TE21-2, and TE21-3 respectively (see FIG. 4), the relation given by the following formula 20 holds. In this case, the widths along the Y direction of the terraces TE21-1, TE21-2, and TE21-3 can be made substantially the same as the widths along the Y direction of the terraces TE1-1, TE1-2, TE1-3, TE1-4, TE1-5, and TE1-6 of the stair structure STST1.

W_{TE21-1}≈W_{TE21-2}≈W_{TE21-3}(≈W_{TE1-1}≈W_{TE1-2}≈W_{TE1-3}≈W_{TE1-4}≈W_{TE1-5}≈W_{TE1-6}) Formula 20

The stair structure STST22 is placed on the +Y side of the center CP2 (see FIG. 2) of the laminated body 20-1. The stair structure STST22 becomes lower stepwise in height above the surface 2a of the substrate 2 when going away in the +Y direction from the center CP2. The stair structure STST22 has a plurality of terraces TE22-1 to TE22-3 and a plurality of steps ST22-1 to ST22-3. In XY plan view, when going away in the +Y direction from the center CP2, the terrace TE22-1, step ST22-1, terrace TE22-2, step ST22-2, terrace TE22-3, and step ST22-3 are arranged in that order. Each terrace TE22-1 to TE22-3 extends along XY directions. Each step ST22-1 to ST22-3 extends along XZ directions.

Letting H_{TE22-1}, H_{TE22-2}, and H_{TE22-3} be the heights along the Z direction of the terraces TE22-1, TE22-2, and TE22-3 respectively above the surface 2a of the substrate 2 (see FIG. 4), the relation given by the following formula 21 holds.

H_{TE22-1}>H_{TE22-2}>H_{TE22-3} Formula 21

The differences between adjacent heights from among the heights along the Z direction of the terraces TE22-1, TE22-2, and TE22-3 are substantially even, and the following formula 22 holds.

H_{TE22-1}−H_{TE22-2}≈H_{TE22-2}−H_{TE22-3}≈H_{TE22-3} Formula 22

Accordingly, letting G_{ST22-1}, G_{ST22-2}, and G_{ST22-3} be the widths along the Z direction of the steps ST22-1, ST22-2, and ST22-3 respectively, they are substantially even, and the relation given by the following formula 23 holds. In this case, the widths along the Z direction of the steps ST22-1, ST22-2, and ST22-3 can be made substantially the same as the widths along the Z direction of the steps ST2-1, ST2-2, ST2-3, ST2-4, ST2-5, and ST2-6 of the stair structure STST2.

G_{ST22-1}≈G_{ST22-2}≈G_{ST22-3}(≈G_{ST2-1}≈G_{ST2-2}≈G_{ST2-3}≈G_{ST2-4}≈G_{ST2-5}≈G_{ST2-6}) Formula 23

Letting W_{TE22-1}, W_{TE22-2}, and W_{TE22-3} be the widths along the Y direction of the terraces TE22-1, TE22-2, and TE22-3 respectively (see FIG. 4), the relation given by the following formula 24 holds. In this case, the widths along the Y direction of the terraces TE22-1, TE22-2, and TE22-3 can be made substantially the same as the widths along the Y direction of the terraces TE2-1, TE2-2, TE2-3, TE2-4, TE2-5, and TE2-6 of the stair structure STST2.

W_{TE22-1}≈W_{TE22-2}≈W_{TE22-3}(≈W_{TE2-1}≈W_{TE2-2}≈W_{TE2-3}≈W_{TE2-4}≈W_{TE2-5}≈W_{TE2-6}) Formula 24

The stair structure STST23 is placed on the +X side of the center CP2 (see FIG. 2) of the laminated body 20-1. The stair structure STST23 becomes lower stepwise in height above the surface 2a of the substrate 2 when going away in the +X direction from the center CP2. The stair structure STST23 has a plurality of terraces TE23-1 to TE23-3 and a plurality of steps ST23-1 to ST23-3. In XY plan view, when going away in the +X direction from the center CP2, the terrace TE23-1, step ST23-1, terrace TE23-2, step ST23-2, terrace TE23-3, and step ST23-3 are arranged in that order. Each terrace TE23-1 to TE23-3 extends along XY directions. Each step ST23-1 to ST23-3 extends along YZ directions.

Letting H_{TE23-1}, H_{TE23-2}, and H_{TE23-3} be the heights along the Z direction of the terraces TE23-1, TE23-2, and TE23-3 respectively above the surface 2a of the substrate 2 (see FIG. 4), the relation given by the following formula 25 holds.

H_{TE23-1}>H_{TE23-2}>H_{TE23-3} Formula 25

The differences between adjacent heights from among the heights along the Z direction of the terraces TE23-1, TE23-2, and TE23-3 are substantially even, and the following formula 26 holds.

H_{TE23-1}−H_{TE23-2}≈H_{TE23-2}−H_{TE23-3}≈H_{TE23-3} Formula 26

Accordingly, letting G_{ST23-1}, G_{ST23-2}, and G_{ST23-3} be the widths along the Z direction of the steps ST23-1, ST23-2, and ST23-3 respectively, they are substantially even, and the relation given by the following formula 27 holds. In this case, the widths along the Z direction of the steps ST23-1, ST23-2, and ST23-3 can be made substantially the same as the widths along the Z direction of the steps ST3-1, ST3-2, ST3-3, ST3-4, ST3-5, and ST3-6 of the stair structure STST3.

G_{ST23-1}≈G_{ST23-2}≈G_{ST23-3}(≈G_{ST3-1}≈G_{ST3-2}≈G_{ST3-3}≈G_{ST3-4}≈G_{ST3-5}≈G_{ST3-6}) Formula 27

Letting W_{TE23-1}, W_{TE23-2}, and W_{TE23-3} be the widths along the X direction of the terraces TE23-1, TE23-2, and TE23-3 respectively, the relation given by the following formula 28 holds. In this case, the widths along the X direction of the terraces TE23-1, TE23-2, and TE23-3 can be made substantially the same as the widths along the X direction of the terraces TE3-1, TE3-2, TE3-3, TE3-4, TE3-5, and TE3-6 of the stair structure STST3.

W_{TE23-1}≈W_{TE23-2}≈W_{TE23-3}(≈W_{TE3-1}≈W_{TE3-2}≈W_{TE3-3}≈W_{TE3-4}≈W_{TE3-5}≈W_{TE3-6}) Formula 28

The stair structure STST24 is placed on the −X side of the center CP2 (see FIG. 2) of the laminated body 20-1. The stair structure STST24 becomes lower stepwise in height above the surface 2a of the substrate 2 when going away in the −X direction from the center CP2. The stair structure STST24 has a plurality of terraces TE24-1 to TE24-3 and a plurality of steps ST24-1 to ST24-3. In XY plan view, when going away in the −X direction from the center CP2, the terrace TE24-1, step ST24-1, terrace TE24-2, step ST24-2, terrace TE24-3, and step ST24-3 are arranged in that order. Each terrace TE24-1 to TE24-3 extends along XY directions. Each step ST24-1 to ST24-3 extends along YZ directions.

Letting H_{TE24-1}, H_{TE24-2}, and H_{TE24-3} be the heights along the Z direction of the terraces TE24-1, TE24-2, and TE24-3 respectively above the surface 2a of the substrate 2 (see FIG. 4), the relation given by the following formula 29 holds.

H_{TE24-1}>H_{TE24-2}>H_{TE24-3} Formula 29

The differences between adjacent heights from among the heights along the Z direction of the terraces TE24-1, TE24-2, and TE24-3 are substantially even, and the following formula 30 holds.

H_{TE24-1}−H_{TE24-2}≈H_{TE24-2}−H_{TE24-3}≈H_{TE24-3} Formula 30

Accordingly, letting G_{ST24-1}, G_{ST24-2}, and G_{ST24-3} be the widths along the Z direction of the steps ST24-1, ST24-2, and ST24-3 respectively, they are substantially even, and the relation given by the following formula 31 holds. In this case, the widths along the Z direction of the steps ST24-1, ST24-2, and ST24-3 can be made substantially the same as the widths along the Z direction of the steps ST4-1, ST4-2, ST4-3, ST4-4, ST4-5, and ST4-6 of the stair structure STST4.

G_{ST24-1}≈G_{ST24-2}≈G_{ST24-3}(≈G_{ST4-1}≈G_{ST4-2}≈G_{ST4-3}≈G_{ST4-4}≈G_{ST4-5}≈G_{ST4-6}) Formula 31

Letting K_{TE24-1}, W_{TE24-2}, and W_{TE24-3} be the widths along the X direction of the terraces TE24-1, TE24-2, and TE24-3 respectively, the relation given by the following formula 32 holds. In this case, the widths along the X direction of the terraces TE24-1, TE24-2, and TE24-3 can be made substantially the same as the widths along the X direction of the terraces TE4-1, TE4-2, TE4-3, TE4-4, TE4-5, and TE4-6 of the stair structure STST4.

W_{TE24-1}≈W_{TE24-2}≈W_{TE24-3}(≈W_{TE4-1}≈W_{TE4-2}≈W_{TE4-3}≈W_{TE4-4}≈W_{TE4-5}≈W_{TE4-6}) Formula 32

In each laminated body 20, an insulating film (second insulating layer) IF2 and an insulating film (first insulating layer) IF1 are repeatedly stacked one over another. FIGS. 1, 2, 4 illustrate a configuration where an insulating film 112 and an insulating film IF1 are alternately stacked one over another three times, as that of the laminated body 20-1. In the laminated body 20-1 shown in FIG. 4, on the substrate 2 and the insulating film 4, an insulating film IF2-1, an insulating film IF1-1, an insulating film IF2-2, an insulating film IF1-2, an insulating film IF2-3, and an insulating film IF1-3 are stacked one over another in that order. The configuration of the laminated bodies 20-2, 20-3 is the same as that of the laminated body 20-1.

In comparison of the stair structure STST21 of the laminated body 20 with the stair structure STST1 of the laminated body 10, the stair structure STST21 is a three-stair structure while the stair structure STST1 is a five-stair structure. Accordingly, the areas of the laminated bodies 20-1, 20-2, 20-3 in XY plan view are smaller than the areas of the laminated bodies 10-1, 10-2 in XY plan view. For example, the maximum widths WX20-1, WX20-2, WX20-3 along the X direction of the laminated bodies 20-1, 20-2, 20-3 are smaller than the maximum widths WX10-1, WX10-2 along the X direction of the laminated bodies 10-1, 10-2. The maximum widths WY20-1, WY20-2, WY20-3 along the Y direction of the laminated bodies 20-1, 20-2, 20-3 are smaller than the maximum widths WY10-1, WY10-2 along the Y direction of the laminated bodies 10-1, 10-2. Note that the maximum width WX20-2 along the X direction of the laminated body 20-2 located in the center along the X direction from among the laminated bodies 20-1, 20-2, 20-3 is to some extent (e.g., about twice) greater than the maximum widths WX20-1, WX20-3 along the X direction of the other laminated bodies 20-1, 20-3. The maximum widths WY20-1, WY20-2, WY20-3 along the Y direction of the laminated bodies 20-1, 20-2, 20-3 are substantially even.

The height of the laminated bodies 20-1, 20-2, 20-3 in YZ cross-sectional view is lower than the height of the laminated bodies 10-1, 10-2 in XZ cross-sectional view. Further, no via plugs are connected to the ends of the insulating films IF2-3, IF2-2, IF2-1 respectively covered by the terraces TE21-1, TE21-2, TE21-3 of the insulating films IF1-3, IF1-2, IF1-1 in the stair structure STST21 of the laminated body 20, whereas the via plugs VP-1, VP-2, VP-3, VP-4, VP-5 are connected to the ends (lead portions WLa-5, WLa-4, WLa-3, WLa-2, WLa-1) of the conductive films WL-5, WL-4, WL-3, WL-2, WL-1 respectively covered by the terraces TE3-1, TE3-2, TE3-3, TE3-4, TE3-5 of the insulating films IF1-5, IF1-4, IF1-3, IF1-2, IF1-1 in the stair structure STST3 of the laminated body 10.

Each laminated body 30 has a stair structure. For example, as shown in FIG. 5B, the laminated body 30-1 has a plurality of stair structures STST31 to STST34. FIG. 5B is an enlarged perspective view illustrating the configuration of the laminated body 30.

The stair structure STST31 is placed on the -Y side of the center CP3 (see FIG. 2) of the laminated body 30-1. The stair structure STST31 becomes lower stepwise in height above the surface 2a of the substrate 2 when going away in the -Y direction from the center CP3. The stair structure STST31 has a plurality of terraces TE31-1, TE31-2 and a plurality of steps ST31-1, ST31-2. In XY plan view, when going away in the −Y direction from the center CP3, the terrace TE31-1, step ST31-1, terrace TE31-2, and step ST31-2 are arranged in that order. Each terrace TE31-1, TE31-2 extends along XY directions. Each step ST31-1, ST31-2 extends along XZ directions.

Letting H_{TE31-1} and H_{TE31-2} be the heights along the Z direction of the terraces TE31-1 and TE31-2 respectively above the surface 2a of the substrate 2 (see FIG. 4), the relation given by the following formula 33 holds.

H_{TE31-1}>H_{TE31-2} Formula 33

The differences between adjacent heights from among the heights along the Z direction of the terraces TE31-1 and TE31-2 are substantially even, and the following formula 34 holds.

H_{TE31-1}−H_{TE31-2}≈H_{TE31-2} Formula 34

Accordingly, letting G_{ST33-1} and G_{ST31-2} be the widths along the Z direction of the steps ST31-1 and ST31-2 respectively, they are substantially even, and the relation given by the following formula 35 holds. In this case, the widths along the Z direction of the steps ST31-1 and ST31-2 can be made substantially the same as the widths along the Z direction of the steps ST1-1, ST1-2, ST1-3, ST1-4, ST1-5, and ST1-6 of the stair structure STST1.

G_{ST31-1}≈G_{ST31-2}(≈G_{ST1-1}≈G_{ST1-2}≈G_{ST1-3}≈G_{ST1-4}≈G_{ST1-5}≈G_{ST1-6}) Formula 35

Letting W_{TE31-1} and W_{TE31-2} be the widths along the Y direction of the terraces TE31-1 and TE31-2 respectively, the relation given by the following formula 36 holds. In this case, the widths along the Y direction of the terraces TE31-1 and TE31-2 can be made substantially the same as the widths along the Y direction of the terraces TE1-1, TE1-2, TE1-3, TE1-4, TE1-5, and TE1-6 of the stair structure STST1.

W_{TE31-1}≈W_{TE31-2}(≈W_{TE1-1}≈W_{TE1-2}≈W_{TE1-3}≈W_{TE1-4}≈W_{TE1-5}≈W_{TE1-6}) Formula 36

The stair structure STST32 is placed on the +Y side of the center CP3 (see FIG. 2) of the laminated body 30-1. The stair structure STST32 becomes lower stepwise in height above the surface 2a of the substrate 2 when going away in the +Y direction from the center CP3. The stair structure STST32 has a plurality of terraces TE32-1, TE32-2 and a plurality of steps ST32-1, ST32-2. In XY plan view, when going away in the +Y direction from the center CP3, the terrace TE32-1, step ST32-1, terrace TE32-2, and step ST32-2 are arranged in that order. Each terrace TE32-1, TE32-2 extends along XY directions. Each step ST32-1, ST32-2 extends along XZ directions.

Letting H_{TE32-1} and H_{TE32-2} be the heights along the Z direction of the terraces TE32-1 and TE32-2 respectively above the surface 2a of the substrate 2 (see FIG. 4), the relation given by the following formula 37 holds.

H_{TE32-1}>H_{TE32-2} Formula 37

The differences between adjacent heights from among the heights along the Z direction of the terraces TE31-1 and TE31-2 are substantially even, and the following formula 38 holds.

H_{TE32-1}−H_{TE32-2}≈H_{TE32-2} Formula 38

Accordingly, letting G_{ST32-1} and G_{ST32-2} be the widths along the Z direction of the steps ST32-1 and ST32-2 respectively, they are substantially even, and the relation given by the following formula 39 holds. In this case, the widths along the Z direction of the steps ST32-1 and ST32-2 can be made substantially the same as the widths along the Z direction of the steps ST2-1, ST2-2, ST2-3, ST2-4, ST2-5, and ST2-6 of the stair structure STST2.

G_{ST32-1}≈G_{ST32-2}(≈G_{ST2-1}≈G_{ST2-2}≈G_{ST2-3}≈G_{ST2-4}≈G_{ST2-5}≈G_{ST2-6}) Formula 39

Letting W_{TE32-1} and W_{TE32-2} be the widths along the Y direction of the terraces TE32-1 and TE32-2 respectively, the relation given by the following formula 40 holds. In this case, the widths along the Y direction of the terraces TE32-1 and TE32-2 can be made substantially the same as the widths along the Y direction of the terraces TE2-1, TE2-2, TE2-3, TE2-4, TE2-5, and TE2-6 of the stair structure STST2.

W_{TE32-1}≈W_{TE32-2}(≈W_{TE2-1}≈W_{TE2-2}≈W_{TE2-3}≈W_{TE2-4}≈W_{TE2-5}≈W_{TE2-6}) Formula 40

The stair structure STST33 is placed on the +X side of the center CP3 (see FIG. 2) of the laminated body 30-1. The stair structure STST33 becomes lower stepwise in height above the surface 2a of the substrate 2 when going away in the +X direction from the center CP3. The stair structure STST33 has a plurality of terraces TE33-1, TE33-2 and a plurality of steps ST33-1, ST33-2. In XY plan view, when going away in the +X direction from the center CP3, the terrace TE33-1, step ST33-1, terrace TE33-2, and step ST33-2 are arranged in that order. Each terrace TE33-1, TE33-2 extends along XY directions. Each step ST33-1, ST33-2 extends along YZ directions.

Letting H_{TE33-1} and H_{TE33-2} be the heights along the Z direction of the terraces TE33-1 and TE33-2 respectively above the surface 2a of the substrate 2 (see FIG. 4), the relation given by the following formula 41 holds.

H_{TE33-1}>H_{TE33-2} Formula 41

The differences between adjacent heights from among the heights along the Z direction of the terraces TE33-1 and TE33-2 are substantially even, and the following formula 42 holds.

H_{TE33-1}−H_{TE33-2}≈H_{TE33-2} Formula 42

Accordingly, letting G_{ST33-1} and G_{ST33-2} be the widths along the Z direction of the steps ST33-1 and ST33-2 respectively, they are substantially even, and the relation given by the following formula 43 holds. In this case, the widths along the Z direction of the steps ST33-1 and ST33-2 can be made substantially the same as the widths along the Z direction of the steps ST3-1, ST3-2, ST3-3, ST3-4, ST3-5, and ST3-6 of the stair structure STST3.

G_{ST33-1}≈G_{ST33-2}(≈G_{ST3-1}≈G_{ST3-2}≈G_{ST3-3}≈G_{ST3-4}≈G_{ST3-5}≈G_{ST3-6}) Formula 43

Letting W_{TE33-1} and W_{TE33-2} be the widths along the X direction of the terraces TE33-1 and TE33-2 respectively, the relation given by the following formula 44 holds. In this case, the widths along the X direction of the terraces TE33-1 and TE33-2 can be made substantially the same as the widths along the X direction of the terraces TE3-1, TE3-2, TE3-3, TE3-4, TE3-5, and TE3-6 of the stair structure STST3.

W_{TE33-1}≈W_{TE33-2}(≈W_{TE3-1}≈W_{TE3-2}≈W_{TE3-3}≈W_{TE3-4}≈W_{TE3-5}≈W_{TE3-6}) Formula 44

The stair structure STST34 is placed on the −X side of the center CP3 (see FIG. 2) of the laminated body 30-1. The stair structure STST34 becomes lower stepwise in height above the surface 2a of the substrate 2 when going away in the −X direction from the center CP3. The stair structure STST34 has a plurality of terraces TE34-1, TE34-2 and a plurality of steps ST34-1, ST34-2. In XY plan view, when going away in the −X direction from the center CP3, the terrace TE34-1, step ST34-1, terrace TE34-2, and step ST34-2 are arranged in that order. Each terrace TE34-1, TE34-2 extends along XY directions. Each step ST34-1, ST34-2 extends along YZ directions.

Letting H_{TE34-1} and H_{TE34-2} be the heights along the Z direction of the terraces TE34-1 and TE34-2 respectively above the surface 2a of the substrate 2 (see FIG. 4), the relation given by the following formula 45 holds.

H_{TE34-1}>H_{TE34-2} Formula 45

The differences between adjacent heights from among the heights along the Z direction of the terraces TE34-1 and TE34-2 are substantially even, and the following formula 46 holds.

H_{TE34-1}−H_{TE34-2}≈H_{TE34-2} Formula 46

Accordingly, letting G_{ST34-1} and G_{ST34-2} be the widths along the Z direction of the steps ST34-1 and ST34-2 respectively, they are substantially even, and the relation given by the following formula 47 holds. In this case, the widths along the Z direction of the steps ST34-1 and ST34-2 can be made substantially the same as the widths along the Z direction of the steps ST4-1, ST4-2, ST4-3, ST4-4, ST4-5, and ST4-6 of the stair structure STST4.

G_{ST34-1}≈G_{ST34-2}(≈G_{ST4-1}≈G_{ST4-2}≈G_{ST4-3}≈G_{ST4-4}≈G_{ST4-5}≈G_{ST4-6}) Formula 47

Letting W_{TE34-1} and W_{TE34-2} be the widths along the X direction of the terraces TE34-1 and TE34-2 respectively, the relation given by the following formula 48 holds. In this case, the widths along the X direction of the terraces TE34-1 and TE34-2 can be made substantially the same as the widths along the X direction of the terraces TE4-1, TE4-2, TE4-3, TE4-4, TE4-5, and TE4-6 of the stair structure STST4.

W_{TE34-1}≈W_{TE34-2}(≈W_{TE4-1}≈W_{TE4-2}≈W_{TE4-3}≈W_{TE4-4}≈W_{TE4-5}≈W_{TE4-6}) Formula 48

In each laminated body 30, an insulating film (second insulating layer) IF2 and an insulating film (first insulating layer) IF1 are repeatedly stacked one over another. FIGS. 1, 2 illustrate a configuration where an insulating film IF2 and an insulating film IF1 are alternately stacked one over another two times, as that of the laminated bodies 30-1, 30-2, 30-3.

In comparison of the stair structure STST31 of the laminated body 30 with the stair structure STST1 of the laminated body 10, the stair structure STST31 is a two-stair structure while the stair structure STST1 is a five-stair structure. Accordingly, the areas of the laminated bodies 30-1, 30-2, 30-3 in XY plan view are smaller than the areas of the laminated bodies 10-1, 10-2 in XY plan view. For example, the maximum widths WX30-1, WX30-2, WX30-3 along the X direction of the laminated bodies 30-1, 30-2, 30-3 are smaller than the maximum widths WX10-1, WX10-2 along the X direction of the laminated bodies 10-1, 10-2. The maximum widths WY30-1, WY30-2, WY30-3 along the Y direction of the laminated bodies 30-1, 30-2, 30-3 are smaller than the maximum widths WY10-1, WY10-2 along the Y direction of the laminated bodies 10-1, 10-2. Note that the maximum width WX30-2 along the X direction of the laminated body 30-2 located in the center along the X direction from among the laminated bodies 30-1, 30-2, 30-3 is to some extent (e.g., about twice) greater than the maximum widths WX30-1, WX30-3 along the X direction of the other laminated bodies 30-1, 30-3. The maximum widths WY30-1, WY30-2, WY30-3 along the Y direction of the laminated bodies 30-1, 30-2, 30-3 are substantially even.

The height of the laminated bodies 30-1, 30-2, 30-3 in YZ cross-sectional view is lower than the height of the laminated bodies 10-1, 10-2 in XZ cross-sectional view. Further, no via plugs are connected to the ends of the insulating films IF2 respectively covered by the terraces TE31-1, TE31-2 of the insulating films IF1 in the stair structure STST31 of the laminated body 30, whereas the via plugs VP-1, VP-2, VP-3, VP-4, VP-5 are connected to the ends (lead portions WLa-5, WLa-4, WLa-3, WLa-2, WLa-1) of the conductive films WL-5, WL-4, WL-3, WL-2, WL-1 respectively covered by the terraces TE3-1, TE3-2, TE3-3, TE3-4, TE3-5 of the insulating films IF1-5, IF1-4, IF1-3, IF1-2, IF1-1 in the stair structure STST3 of the laminated body 10.

In comparison of the stair structure STST31 of the laminated body 30 with the stair structure STST21 of the laminated body 20, the stair structure STST31 is a two-stair structure while the stair structure STST21 is a three-stair structure. Accordingly, the areas of the laminated bodies 30-1, 30-2, 30-3 in XY plan view are smaller than the areas of the laminated bodies 20-1, 20-2, 20-3 in XY plan view. The height of the laminated bodies 30-1, 30-2, 30-3 in YZ cross-sectional view is lower than the height of the laminated bodies 20-1, 20-2, 20-3 in YZ cross-sectional view.

For example, the stress of the interlayer insulating film 3 may occur in a direction from the interlayer insulating film 3 toward the laminated body 10. Each laminated body 20 extends along an outer edge of a laminated body 10. Each laminated body 30 extends along an outer edge of a laminated body 10.

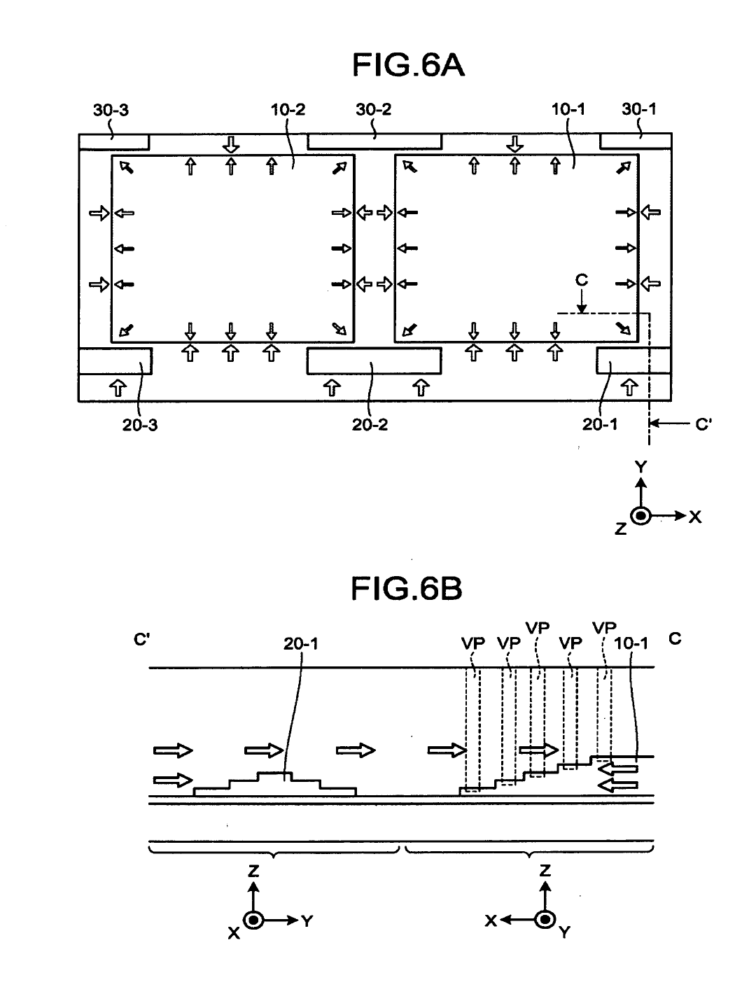

Hence, as shown in FIGS. 6A and 6B, the placement of the laminated bodies 20 and/or the laminated bodies 30 can reduce the volume of the interlayer insulating film 3 to relieve the compressive stress itself that occurs. Further, the laminated bodies 20 and/or the laminated bodies 30 can be made to function as breakwaters against the compressive stress from the interlayer insulating film 3 toward the laminated body 10, so that the stress toward the laminated body 10 can be effectively relieved. Thus, for example, stress acting on via plugs VP indicated by broken lines in FIG. 6B can be reduced, so that the occurrence of a short circuit and/or a disconnection due to stress can be suppressed. FIG. 6A is a diagram illustrating stress relief by the laminated bodies 20 and/or the laminated bodies 30 in the semiconductor device 1 in an XY plane, and FIG. 6B is a diagram illustrating stress relief by the laminated bodies 20 and/or the laminated bodies 30 in the semiconductor device 1 in a YZ cross-section and an XZ cross-section, taken along line C-C′ in FIG. 6A.

To be exact, the difference between the stress of the laminated body 10 on the interlayer insulating film 3 indicated by small hollow arrows in FIGS. 6A and 6B and the stress of the interlayer insulating film 3 on the laminated body 10 indicated by larger hollow arrows in FIGS. 6A and 6B can be regarded as compressive stress as indicated by a broken-line arrow in FIG. 3. Reducing the difference between the stress of the laminated body 10 on the interlayer insulating film 3 and the stress of the interlayer insulating film 3 on the laminated body 10 can be explained to be equivalent to relieving the compressive stress from the interlayer insulating film 3 toward the laminated body 10.

As such, in the embodiment, in the semiconductor device 1, laminated bodies 20 having the stair structure are placed in a periphery of the laminated body 10. Thereby the compressive stress of the interlayer insulating film 3 on the laminated body 10 can be relieved, so that failures due to the compressive stress can be suppressed. As a result, the semiconductor device 1 can be easily highly integrated.

The plurality of laminated bodies 20 provided in the semiconductor device 1, not being limited to the configuration shown in FIGS. 1 and 2, can be changed as long as the compressive stress of the interlayer insulating film 3 on the laminated body 10 can be relieved. For example, if compressive stress which may occur in part of the interlayer insulating film 3 in the periphery region PHR2 is negligibly small compared with compressive stress which may occur in part of the interlayer insulating film 3 in the periphery region PHR1, then the semiconductor device 1 may have a configuration where the laminated bodies 30-1 to 30-3 shown in FIGS. 1 and 2 are omitted.

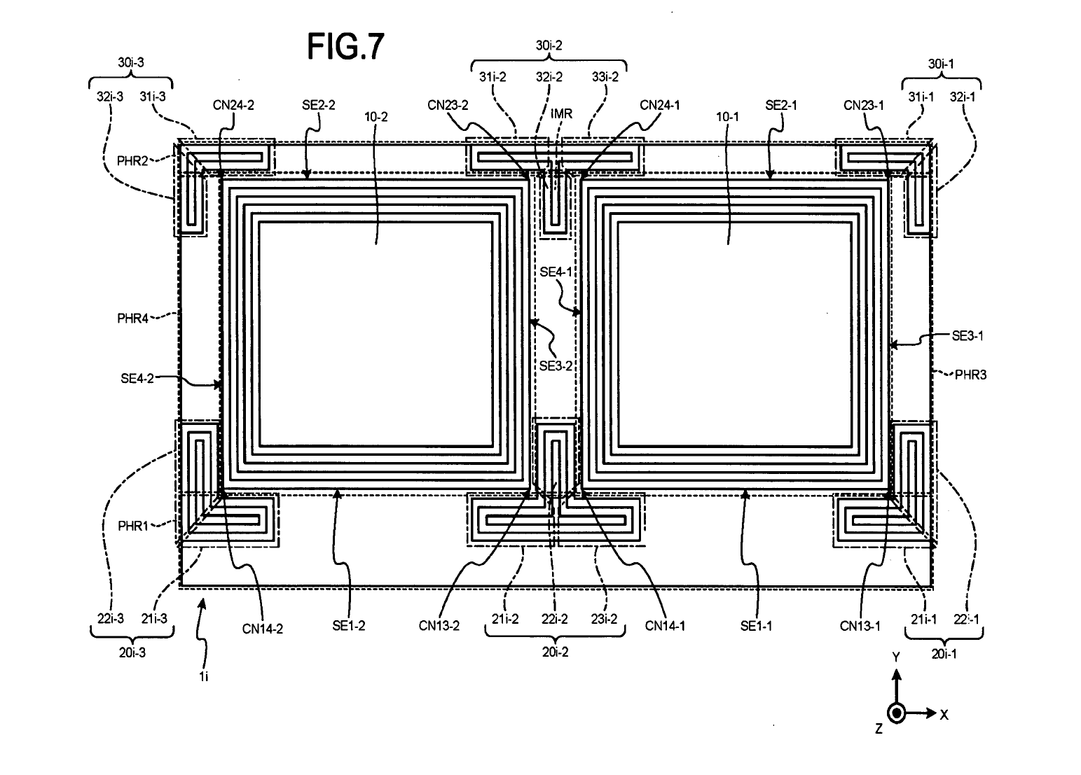

Or, as shown in FIG. 7, for example, if the planar shapes of the laminated bodies 10-1, 10-2 are substantially rectangular, a plurality of laminated bodies 20i provided in the semiconductor device 1i may extend in directions along sides in outer edges of the planar shapes of the laminated bodies 10-1, 10-2.

Specifically, the laminated body 20i-1 extends in the −X direction within the periphery region PHR1 from a position near the corner on the +X side and −Y side of the laminated body 10-1 in the periphery region PHR1 and extends in the +Y direction into the periphery region PHR3. The laminated body 20i-1 is shaped almost like a lying-down L in XY plan view.

The laminated body 20i-2 extends in the −X direction and the +X direction within the periphery region PHR1 from a position near the corner on the −X side and −Y side of the laminated body 10-1 and near the corner on the +X side and −Y side of the laminated body 10-2 in the periphery region PHR1 and extends in the +Y direction into the intermediate region IMR. The laminated body 20i-2 is shaped almost like an inverted T in XY plan view.

The laminated body 20i-3 extends in the +X direction within the periphery region PHR1 from a position near the corner on the −X side and −Y side of the laminated body 10-2 in the periphery region PHR1 and extends in the +Y direction into the periphery region PHR4. The laminated body 20i-3 is shaped almost like an L in XY plan view.

The laminated body 30i-1 extends in the −X direction within the periphery region PHR2 from a position near the corner on the +X side and +Y side of the laminated body 10-1 in the periphery region PHR2 and extends in the −Y direction into the periphery region PHR3. The laminated body 30i-1 is shaped almost like an inverted L in XY plan view.

The laminated body 30i-2 extends in the −X direction and the +X direction within the periphery region PHR2 from a position near the corner on the −X side and +Y side of the laminated body 10-1 and near the corner on the +X side and +Y side of the laminated body 10-2 in the periphery region PHR2 and extends in the −Y direction into the intermediate region IMR. The laminated body 30i-2 is shaped almost like a T in XY plan view.

The laminated body 30i-3 extends in the +X direction within the periphery region PHR2 from a position near the corner on the −X side and +Y side of the laminated body 10-2 in the periphery region PHR2 and extends in the −Y direction into the periphery region PHR4. The laminated body 30i-3 is shaped almost like an inverted L in XY plan view.

More specifically, the laminated body 10-1 has outer edges in a substantially rectangular shape and has a side SE1-1 on the −Y side, a side SE2-1 on the +Y side, a side SE3-1 on the +X side, a side SE4-1 on the −X side, a corner CN13-1 on the +X side and −Y side, a corner CN23-1 on the +X side and +Y side, a corner CN24-1 on the −X side and +Y side, and a corner CN14-1 on the −X side and −Y side. The laminated body 10-2 has outer edges in a substantially rectangular shape and has a side SE1-2 on the −Y side, a side SE2-2 on the +Y side, a side SE3-2 on the +X side, a side SE4-2 on the −X side, a corner CN13-2 on the +X side and −Y side, a corner CN23-2 on the +X side and +Y side, a corner CN24-2 on the −X side and +Y side, and a corner CN14-2 on the −X side and −Y side.

The laminated body 20i-1 has a portion 21i-1 and a portion 22i-1. The portion 21i-1 extends in the −X direction along the side SE1-1 from a position near the corner CN13-1. The portion 22i-1 extends in the +Y direction along the side SE3-1 from a position near the corner CN13-1.

The laminated body 20i-2 has portions 21i-2, 22i-2 and a portion 23i-2. The portion 21i-2 extends in the −X direction along the side SE1-2 from a position near the corner CN13-2. The portion 22i-2 extends in the +Y direction along the side SE3-2 and the side SE4-1 (between the two sides SE3-2, SE4-1) from a position near the corner CN13-2 and the corner CN14-1 (a position between the two corners CN13-2, CN14-1). The portion 23i-2 extends in the +X direction along the side SE1-1 from a position near the corner CN14-l.

The laminated body 20i-3 has a portion 21i-3 and a portion 22i-3. The portion 21i-3 extends in the +X direction along the side SE1-2 from a position near the corner CN14-2. The portion 22i-3 extends in the +Y direction along the side SE4-2 from a position near the corner CN14-2.

The laminated body 30i-1 has a portion 31i-1 and a portion 32i-1. The portion 31i-1 extends in the −X direction along the side SE2-1 from a position near the corner CN23-1. The portion 32i-1 extends in the −Y direction along the side SE3-1 from a position near the corner CN23-1.

The laminated body 30i-2 has portions 31i-2, 32i-2 and a portion 33i-2. The portion 31i-2 extends in the −X direction along the side SE2-2 from a position near the corner CN23-2. The portion 32i-2 extends in the −Y direction along the side SE3-2 and the side SE4-1 (between the two sides SE3-2, SE4-1) from a position near the corner CN23-2 and the corner CN24-1 (a position between the two corners CN23-2, CN24-1). The portion 33i-2 extends in the +X direction along the side SE2-1 from a position near the corner CN24-1.

The laminated body 30i-3 has a portion 31i-3 and a portion 32i-3. The portion 31i-3 extends in the +X direction along the side SE2-2 from a position near the corner CN24-2. The portion 32i-3 extends in the −Y direction along the side SE4-2 from a position near the corner CN24-2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first laminated body in which a conductive film and a first insulating layer are repeatedly placed one over another in a stacking direction, the first laminated body having a first stair structure;
a first semiconductor columnar member extending through the first laminated body in the stacking direction;
a first gate insulating film surrounding the first semiconductor columnar member in plan view and extending through the first laminated body in the stacking direction; and
a second laminated body placed in a periphery of the first laminated body, in which the first insulating layer and a second insulating layer are repeatedly placed one over another in the stacking direction, and having a second stair structure, a width in a first direction of the second laminated body being smaller than a width in the first direction of the first laminated body, the first direction being substantially perpendicular to the stacking direction, and a width in a second direction of the second laminated body being smaller than a width in the second direction of the first laminated body, the second direction being substantially perpendicular to the stacking direction and being substantially perpendicular to the first direction.

2. The semiconductor device according to claim 1, further comprising:
a third laminated body placed in a position different from that of the second laminated body in a periphery of the first laminated body, in which the first insulating layer and the second insulating layer are repeatedly placed one over another in the stacking direction and having a third stair structure, a width in the first direction of the third laminated body being smaller than the width in the first direction of the first laminated body, and a width in the second direction of the third laminated body being smaller than the width in the second direction of the first laminated body.

3. The semiconductor device according to claim 1, wherein
the first laminated body has a planar shape including a corner, and
wherein the second laminated body is placed near the corner of the first laminated body in plan view.

4. The semiconductor device according to claim 2, wherein
the first laminated body has a planar shape including a plurality of corners,
wherein the second laminated body is placed near a first corner of the first laminated body in plan view, and
wherein the third laminated body is placed near a second corner of the first laminated body in plan view.

5. The semiconductor device according to claim 1, wherein
the second laminated body extends along an outer edge of the first laminated body in plan view.

6. The semiconductor device according to claim 2, wherein
the second laminated body extends along an outer edge of the first laminated body in plan view, and
wherein the third laminated body is, in plan view, on the opposite side of the first laminated body from the second laminated body and extends along an outer edge of the first laminated body.

7. The semiconductor device according to claim 1, wherein
the second laminated body is shaped like a prismoid.

8. The semiconductor device according to claim 2, wherein
the third laminated body is shaped like a prismoid.

9. The semiconductor device according to claim 1, wherein
the height of the second laminated body in cross-sectional view is lower than the height of the first laminated body in cross-sectional view.

10. The semiconductor device according to claim 2, wherein
the height of the third laminated body in cross-sectional view is lower than the height of the first laminated body in cross-sectional view.

11. The semiconductor device according to claim 1, wherein
a via plug is electrically connected to an end of the conductive film in the first stair structure, and
wherein a via plug is not electrically connected to an end of the second insulating layer in the second stair structure.

12. The semiconductor device according to claim 1, wherein
the first laminated body has a planar shape including a plurality of sides, and
wherein the second laminated body has:
a first portion extending along a first side of the first laminated body in plan view; and
a second portion extending along a second side adjacent to the first side of the first laminated body in plan view.

13. The semiconductor device according to claim 2, wherein
the first laminated body has a substantially rectangular planar shape including a plurality of sides,
wherein the second laminated body has:
a first portion extending along a first side of the first laminated body in plan view; and
a second portion extending along a second side adjacent to the first side of the first laminated body in plan view, and
wherein the third laminated body has:
a third portion extending along the first side or a third side opposite to the first side of the first laminated body in plan view; and
a fourth portion extending along a fourth side opposite to the second side of the first laminated body in plan view.

14. The semiconductor device according to claim 1, further comprising:
a fourth laminated body in which the conductive film and the first insulating layer are repeatedly placed one over another in the stacking direction, the fourth laminated body having a fourth stair structure;
a second semiconductor columnar member extending through the fourth laminated body in the stacking direction; and
a second gate insulating film surrounding the second semiconductor columnar member in plan view and extending through the fourth laminated body in the stacking direction,
wherein the first laminated body and the fourth laminated body each have a planar shape including a corner, and
wherein the second laminated body is placed between the corner of the first laminated body and the corner of the fourth laminated body in plan view.

15. The semiconductor device according to claim 2, further comprising:
a fourth laminated body in which the conductive film and the first insulating layer are repeatedly placed one over another in the stacking direction, the fourth laminated body having a fourth stair structure;
a second semiconductor columnar member extending through the fourth laminated body in the stacking direction; and
a second gate insulating film surrounding the second semiconductor columnar member in plan view and extending through the fourth laminated body in the stacking direction,
wherein the first laminated body and the fourth laminated body each have a planar shape including a plurality of corners,
wherein the second laminated body is placed between a first corner of the first laminated body and a first corner of the fourth laminated body in plan view, and
wherein the third laminated body is placed between a second corner of the first laminated body and a second corner of the fourth laminated body in plan view.

16. The semiconductor device according to claim 1, further comprising:
a fourth laminated body in which the conductive film and the first insulating layer are repeatedly placed one over another in the stacking direction, the fourth laminated body having a fourth stair structure;
a second semiconductor columnar member extending through the fourth laminated body in the stacking direction; and
a second gate insulating film surrounding the second semiconductor columnar member in plan view and extending through the fourth laminated body in the stacking direction,
wherein the first laminated body and the fourth laminated body each have a substantially rectangular planar shape including a plurality of sides, and
wherein the second laminated body has:
a first portion extending along a first side of the first laminated body in plan view;
a second portion extending between a second side of the first laminated body and a second side of the fourth laminated body, which are opposite to each other, in plan view; and
a third portion extending along a first side of the fourth laminated body in plan view, the second portion being placed between the first portion and the third portion.

17. The semiconductor device according to claim 2, further comprising:
a fourth laminated body in which the conductive film and the first insulating layer are repeatedly placed one over another in the stacking direction, the fourth laminated body having a fourth stair structure;
a second semiconductor columnar member extending through the fourth laminated body in the stacking direction; and
a second gate insulating film surrounding the second semiconductor columnar member in plan view and extending through the fourth laminated body in the stacking direction,
wherein the first laminated body and the fourth laminated body each have a substantially rectangular planar shape including a plurality of sides,
wherein the second laminated body has:
a first portion extending along a first side of the first laminated body in plan view;
a second portion extending between a second side of the first laminated body and a second side of the fourth laminated body, which are opposite to each other, in plan view; and
a third portion extending along a first side of the fourth laminated body in plan view, the second portion being placed between the first portion and the third portion, and
wherein the third laminated body has:
a fourth portion extending along a third side opposite to the first side of the first laminated body in plan view;
a fifth portion extending between the second side of the first laminated body and the second side of the fourth laminated body, which are opposite to each other, in plan view; and
a sixth portion extending along a third side opposite to the first side of the fourth laminated body in plan view, the fifth portion being placed, between the fourth portion and the sixth portion.

18. A semiconductor device comprising:
a first laminated body in which a conductive film and a first insulating layer are repeatedly placed one over another in a stacking direction, the first laminated body having a first stair structure;
a first semiconductor columnar member extending through the first laminated body in the stacking direction;
a first gate insulating film surrounding the first semiconductor columnar member in plan view and extending through the first laminated body in the stacking direction; and
a second laminated body placed in a periphery of the first laminated body and having a second stair structure,
wherein the first laminated body has a planar shape including a plurality of sides, and
wherein the second laminated body has:
a first portion extending along a first side of the first laminated body in plan view; and
a second portion placed continuous with the first portion and extending along a second side adjacent to the first side of the first laminated body in plan view.

19. The semiconductor device according to claim 18, wherein
the height of the second laminated body in cross-sectional view is lower than the height of the first laminated body in cross-sectional view.

20. The semiconductor device according to claim 18, further comprising:
a third laminated body placed in a position different from that of the second laminated body in a periphery of the first laminated body and having a third stair structure,
wherein the first laminated body has a substantially rectangular planar shape including a plurality of sides, and
wherein the third laminated body has:
a third portion extending along the first side or a third side opposite to the first side of the first laminated body in plan view; and
a fourth portion placed continuous with the third portion and extending along a fourth side opposite to the second side of the first laminated body in plan view.
